(19) United States
(12) Patent Application Publication
(10) Pub. No.: US 2014/0000698 A1
(43) Pub. Date: Jan. 2, 2014

(54) METHOD FOR PRODUCING ELECTRICALLY CONDUCTIVE CONTACTS ON SOLAR CELLS, AND SOLAR CELL

(71) Applicants: Henning Nagel, Freiburg (DE); Wilfried Schmidt, Schwaigern (DE)

(72) Inventors: Henning Nagel, Freiburg (DE); Wilfried Schmidt, Schwaigern (DE)

(73) Assignee: SCHOTT SOLAR AG, Mainz (DE)

(21) Appl. No.: 13/994,841

(22) PCT Filed: Dec. 15, 2011
(86) PCT No.: PCT/EP2011/072978

§ 371 Date: Sep. 3, 2013

(30) Foreign Application Priority Data
Dec. 16, 2010 (DE) 10 2010 061 296.0

(51) Int. Cl. H01L 31/02

(52) U.S. Cl. CPC H01L 31/02021
USPC 136/256; 438/98

(57) ABSTRACT

A method for producing contacts made of electrically conductive material on solar cells is provided. The method includes applying a dopant source to at least one face of a substrate; forming phosphosilicate glass by diffusing dopant into the substrate in a first thermal step; locally applying laser radiation to the substrate in regions in which the electrically conductive material is to be applied in order to form the electrically conductive contact; measuring the layer resistivity developed in the surface region of the substrate on the dopant source side; applying the electrically conductive material to the lasered areas; measuring the specific contact resistance between the lasered area and the electrically conductive material; determining a pulse energy density range of the laser beam from the measured values; applying laser radiation having a pulse energy density within the determined pulse energy density range.

The invention relates to a method for producing contacts made of electrically conductive material on a group of solar cells. Furthermore, the invention relates to a solar cell, comprising a substrate made of crystalline silicon with an emitter on which electrically conductive contacts are formed in certain areas.

A general problem in the electrical contacting of crystalline silicon solar cells consists in the necessity of high surface concentrations of dopant for a low contact transition resistance. These exhibit the drawback that an increased recombination of excess minority charge carriers occurs and the short-circuit current is thereby reduced. If the strongly diffused area is located on the front face of the solar cell, the short-circuit current is reduced for short wavelengths of light in the blue spectral region; that is, the internal quantum yield is low in this spectral region. If the strongly diffused area is located on the back side of the solar cell, the short-circuit current is reduced for long wavelengths of light in the near-infrared region. Furthermore, the free charge carriers in the strongly doped area are responsible for parasitic absorption for light in the near-infrared region.

In order to solve this problem it is known that a high dopant concentration is produced essentially only locally under the metallization. However, for this purpose, a technically very demanding, positionally precise application of the metallization is required.

Known from EP B 1 738 402 is a laser doping of solids with a line-focused laser beam and the production of solar cell emitters based thereon. In this process, a dopant source is applied to a crystalline silicon substrate (wafer) by spin coating methods or screen printing or film printing methods in order to then fuse regions of the substrate beneath the dopant source with a focused laser beam, so that the dopant diffuses into the fused region and recrystallizes during cooling of the fused region.

A high dopant concentration can be obtained in desired areas by way of these measures. The corresponding method can be used for producing an emitter region or an ohmic contact between a semiconductor and a metal.

Described in the literature reference KÖHLER et al.: “Laser Doped Selective Emitters Yield 0.5% Efficiency Gain,” Proceedings of the 24th European Photovoltaic Energy Conference 2009, 1847, is a corresponding method, in which a laser beam having a pulse energy density of between 1 J/cm² and 18 J/cm² is employed at laser pulse durations of between 10 ns and 200 ns. Selective emitters shall be produced by using a corresponding method to improve the efficiency of a solar cell.

A doping of silicon solar cells by means of laser radiation is also described in the literature reference AMETOWOBLA et al., “Improved Laser Doping for Silicon Solar Cells.”

According to U.S. Pat. No. 4,147,563, a laser-induced diffusion is carried out in order to form a pn junction in a solar cell.

Proposed in the literature reference CARLSSON, C. et al., “Laser Doped Selective Emitters Yield 0.5% Efficiency Gain,” 21st European Photovoltaic Conference, Sep. 4-8, 2006, Dresden, pages 938 to 940, is a method for forming a selective emitter by means of laser application, wherein the wafer is open-doped. Measurement results relating to the layer resistivity in the lasered and non-lasered area are presented.

Known from U.S. Pat. No. 6,429,037 is a solar cell with a selective emitter.

The present invention is based on the problem of further developing a method for producing electrically conductive contacts on crystalline silicon solar cells so that the intrinsic drawbacks of the prior art are avoided, in particular so as to reproducibly produce a good electrically conductive connection between the contacts and the solar cell with the avoidance of an increased dopant concentration in the region of the electrically conductive contacts, that is, so as to minimize the contact transition resistance in the connection region.

In order to solve this problem, in terms of the method, the invention essentially provides that initially the following method steps are carried out for at least one solar cell form the group of solar cells:

a) homogeneously applying a dopant source to at least one face of a substrate made of crystalline silicon over the whole area,

b) forming phosphosilicate glass by diffusing dopant into the substrate in a first thermal step at a temperature T₁ over a time t₁,

c) locally applying laser radiation to the substrate in regions in which the electrically conductive material is to be applied in order to form the electrically conductive contact, wherein the phosphosilicate glass is removed before or after the application of the laser radiation, and

d) measuring the layer resistivity ρ_{SH} developed in the surface region of the substrate on the dopant source side, both in and laterally outside of the lasered area, as a function of the pulse energy density of the laser beam applied to the substrate,

e) applying the electrically conductive material to the lasered areas,

f) measuring the specific contact resistance between the lasered area and the electrically conductive material applied thereto as a function of the pulse energy density of the laser beam applied to the substrate,

g) determining a pulse energy density range of the laser beam from the measured values for which the layer resistivity ρ_{SH} in the lasered area is reduced between 0% and 30% compared to the layer resistivity outside the lasered area and the specific contact resistance between the lasered area and the electrically conductive material applied thereto for forming the electrically conductive contact is between 0 mΩcm² and 10 mΩcm²,

and then the following method steps are carried out for serial production:

h) applying laser radiation having a pulse energy density within the determined pulse energy density range to the remaining solar cells from the group in the areas of the solar cells to be contacted after performing at least the method steps a) and b).

It has been found that, in the case when the layer resistivity in the lasered region is reduced by at most 35%, in particular by 10% to 25%, compared to the layer resistivity outside the lasered area, and the specific contact resistance in the lasered area is at most 10 mΩcm², the recombinations that negatively influence the efficiency of the solar cell are strongly reduced. At the same time, however, a low-loss current collection is possible.

Surprisingly, it could be established that, when the layer resistivity in the lasered area is slightly changed compared to the non-lasered area, a sudden, nearly abrupt reduction in the specific contact resistance results, so that, as a result thereof, the desired electrically conductive contact is ensured, while, at the same time, the internal quantum yield is not negatively influenced to such an extent that the efficiency of the solar cell is noticeably negatively influenced.

Measurements have shown that, taking into consideration the adjustment of the layer resistivity and specific contact transition resistance according to the invention, the internal quantum yield in the lasered area is reduced only by at most 10% during laser application to the front face of the solar cell in the wavelength range between 400 nm and 600 nm, and the internal quantum yield in the lasered area is reduced likewise by at most 10% during laser application to the back side of the solar cell in the wavelength range of 900 nm to 1200 nm.

The teaching according to the invention is aimed at enabling the reproducible production of solar cells in serial production, wherein optimal conditions are afforded in the region of the electrically conductive contacts, that is, the usually occurring, undesired recombination is reduced, without the internal quantum yield being influenced in such a way that the efficiency of the solar cell is noticeably negatively influenced. Utilized for this purpose is the previously discussed knowledge wherein initially the impulse energy density range of the laser radiation applied to the solar cells at which the desired layer resistivity and contact resistance can be established is determined on one or more solar cells.

Once the corresponding values have been determined, identical parameters are utilized for the other solar cells being produced, with method steps employed in production for the individual solar cells specified for the measurements being used correspondingly for serial production.

For determination of the pulse energy density range, laser radiation of different pulse energy density may also be applied to several solar cells of the group. The measurements on one solar cell or the measurements on several solar cells are insofar to be understood as being synonymous.

The pulse energy density needed to achieve the desired maximal reduction in the layer resistivity with simultaneous reduction of the contact transition resistance lies in the range between 1.0 J/cm² and 2.2 J/cm², in particular in the range between 1.2 J/cm² and 1.6 J/cm². The respective values apply not only to phosphorus as dopant, but also to As, Sb, Bi, B, Al, In, Ga, Ti.

In particular, the invention is characterized in that a dopant is applied to the substrate (wafer) with a dopant concentration such that, after thermal diffusion, the content of electrically active dopant relative to the total dopant content lies between 0.01 and 1, in particular between 0.05 and 0.5. This applies to a layer of thickness D with 90 nm≦T≦110 nm, preferably D of about 100 nm, starting from the surface of the substrate.

The dopants, which are not electrically active, are predominantly bound in precipitates in this case.

The removal of the phosphosilicate glass can occur in different stages of solar cell production.

Thus, according to one alternative, there exists the possibility that, after formation of the phosphosilicate glass, it is removed, after which the laser radiation is applied to the solar cell, the substrate is subsequently exposed to a temperature T₂ over a time t₂ in a second thermal treatment step, and then oxide formed on the substrate is removed.

A second alternative provides that, after formation of the phosphosilicate glass, the laser radiation is applied to the solar cell and subsequently the phosphosilicate glass is removed, after which the substrate is exposed to a temperature T₂ over a time t₂ in a second thermal treatment step and then oxide formed on the substrate is removed.

According to a third variant, it is provided that, after formation of the phosphosilicate glass, the laser radiation is applied to the solar cell and subsequently the substrate is exposed to a temperature T₂ over a time t₂ in a second thermal treatment step, after which the phosphosilicate glass is removed.

Another variant provides that, after formation of the phosphosilicate glass, it is removed and subsequently the substrate is exposed to a temperature T₂ over a time t₂ in a second thermal treatment step, after which the laser radiation is applied to the solar cell and, finally, the oxide formed on the substrate is removed.

There also exists the possibility that, after formation of the phosphosilicate glass, it is removed and subsequently the substrate is exposed to a temperature T₂ over a time t₂ in a second thermal step, after which the oxide formed on the substrate is removed and, finally, the laser radiation is applied to the solar cell.

According to another alternative, it is provided that, after formation of the phosphosilicate glass, the substrate is exposed to a temperature T₂ over a time t₂ in a second thermal treatment step, after which the laser radiation is applied to the solar cell and, finally, the phosphosilicate glass is removed.

There also exists the possibility that, after formation of the phosphosilicate glass, the substrate is exposed to a temperature T₂ over a time t₂ in a second thermal treatment step, after which the phosphosilicate glass is removed and, finally, the laser radiation is applied to the solar cell.

After conclusion of the above discussed method steps, the electrically conductive material for forming the contact is then applied. In this process, conventional methods, such as the application of pastes and subsequent sintering or electrodeposition and annealing can be employed in order to apply the electrically conductive material and form the electrical contact.

In particular, it is provided that a medium from the following group is used as the dopant source: aqueous solution, alcoholic solution, solid containing phosphorus as doping agent in a concentration C with 2 at %≦C≦30 at %, in particular 3 at %≦C≦8 at %.

By means of the method according to the invention, the surface region of the substrate beneath the dopant source is fused by application of the laser beam and, as a result, the dopant can diffuse further into the substrate. The pulse energy density of the laser for preferred laser pulse durations in the range between 1 fs and 300 ns results in fusion up to a thickness of 200 nm. The fused layer then recrystallizes on cooling. Structural crystal defects consequently occur exclusively in this region.

Furthermore, the lasering itself should occur in an oxygen-containing atmosphere.

In a further development, it is provided that the substrate is isotextured prior to the thermal diffusion or random pyramids are produced in alkaline etching solution.

The layer resistivity ρ_{SH} of the substrate outside of the lasered areas should be at least 50Ω/ to 250Ω/, preferably 60Ω/ to 200Ω/.

Used as laser radiation is, in particular, one with a laser pulse duration of between 1 fs and 300 ns and/or a repetition rate of between 100 Hz and 1 MHz, preferably of between 1 kHz and 500 kHz.

Regardless thereof, the invention is also characterized in that the first thermal treatment step performed for formation of the phosphosilicate glass is carried out at a temperature T₁ over a time t₁ and/or the second thermal treatment step is carried out at a temperature T₂ over a time t₂ for solar cells arranged stacked one above the other.

There exists the further possibility that the substrate is hydrophilized prior to application of the dopant source.

Another proposal provides that, prior to application of the dopant source, the substrate is hydrophilized in an aqueous solution containing NaOH or KOH or H₂O₂ or ozone, if need be with addition of surfactant.

Alternatively, the invention provides that, prior to application of the dopant source, the substrate is hydrophilized in an aqueous solution containing peroxide disulfate, if need be with addition of surfactant.

Another proposal provides that, prior to application of a dopant source, the substrate is hydrophilized in an aqueous solution containing HCl, possibly with addition of HF and/or surfactant.

A solar cell comprising a substrate made of crystalline silicon with an emitter and electrically conductive contacts formed on it in certain areas is characterized in that the layer resistivity of the surface of the substrate extending over the doped face beneath the electrically conductive contacts is 0% to 25% less than the layer resistivity outside of the electrically conductive contacts and the specific contact resistance between the electrically conductive contact and edge region on the dopant source side lies between 0 mΩcm² and 10 mΩcm².

In particular, it is provided that the layer resistivity of the substrate outside of the electrical contacts is between 50Ω/ and 250Ω/, preferably between 60Ω/ and 200Ω/.

Furthermore, the solar cell is characterized in that crystal defects are present beneath the electrically conductive contacts over a thickness of between 1 nm and 200 nm starting from the edge region on the dopant source side.

The layer resistivity of the substrate outside of the electrical contacts is 50Ω/ to 250Ω/, preferably 60Ω/ to 200Ω/.

The surface phosphorus concentration of the solar cell should be greater than 8×10²⁰ cm⁻³. The phosphorus concentration can be determined by means of secondary ion mass spectrometry (SIMS).

Further details, advantages, and features of the invention ensue not only from the claims, the features to be taken from them—alone and/or in combination—but also from the description of the following embodiment example.

Shown are:

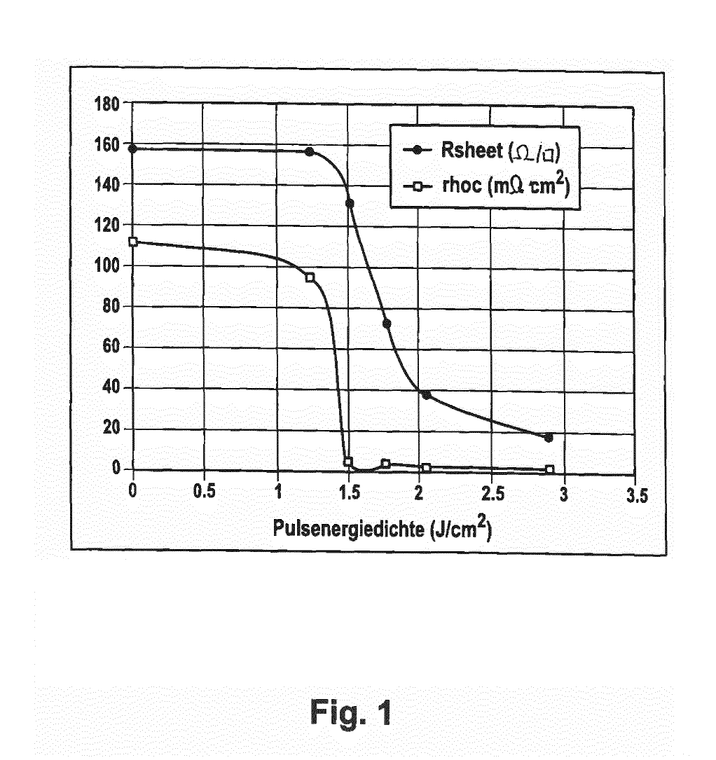

FIG. 1 a representation of specific contact resistance and layer resistivity as a function of pulse energy density and

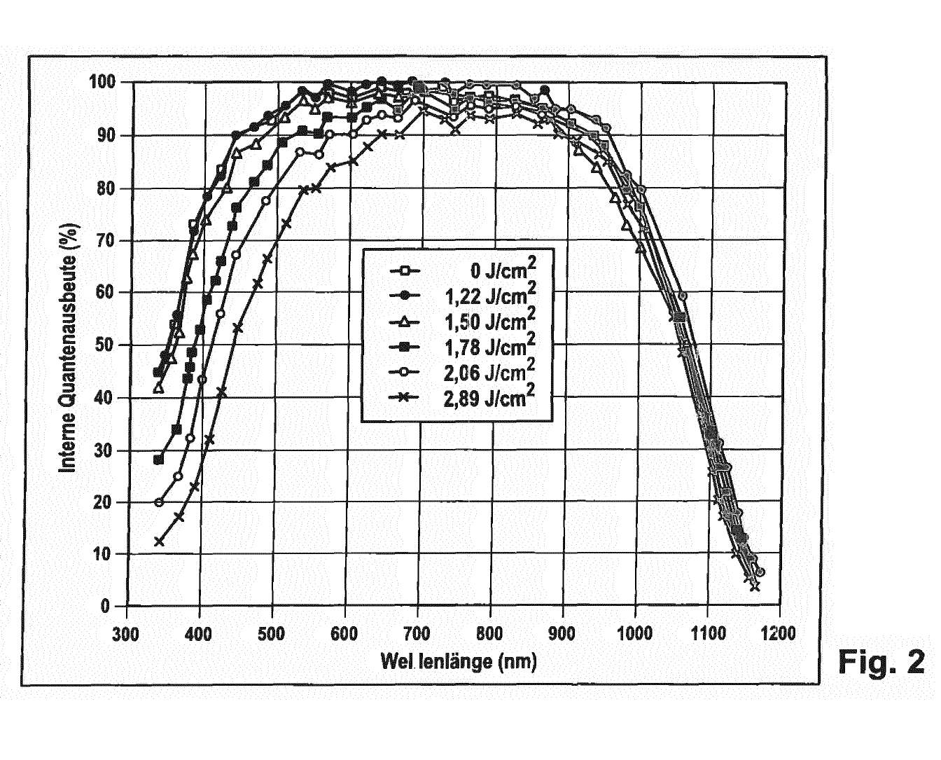

FIG. 2. a representation of internal quantum yield as a function of various pulse energy densities.

In order to produce a solar cell, a dopant source in the form of phosphoric acid with a concentration of 15 wt % phosphorus is applied over the area of one face of a substrate (wafer) made of crystalline p-silicon by means of ultrasonic atomization or dipping.

The phosphorus present as dopant in the dopant source is forced into the substrate (wafer) in a thermal diffusion process. For this purpose, the substrate is exposed to a temperature in the range of between 500° C. and 1000° C. over a period of between 30 min and 120 min. As a result, a surface region becomes negatively conductive, so that the pn junction required for separation of the charge carriers produced by light is formed.

A back-surface field as well as a back-side contact over the whole area can be formed on the back side in a conventional way by diffusion processes. Reference is insofar made to known techniques.

Alternatively, however, a dopant source can be applied to the back side of the substrate in order to accomplish contacting, as in the case of the front face, in the way described below.

In order to prevent an increased recombination of excess minority charge carriers in the area of the required electrical contacts (fingers) due to high surface concentration and a consequent reduction in the short-circuit current, it is provided according to the invention that, in the areas in which a contacting occurs, the dopant source is exposed to laser radiation such that, in the edge region of the substrate on the dopant source side, there results a layer resistivity that is at most 20% less than the layer resistivity outside of the lasered areas. As a result, it is avoided that, owing to an undesired low layer resistivity, the internal quantum yield is reduced in such a way that the efficiency of the solar cell is noticeably negatively influenced. At the same time, the specific contact transition resistance between the lasered area and the electrically conductive material to be applied for forming the electrical contact is adjusted so that values of between 0 mΩcm² and 10 mΩcm² result.

In order to achieve this fine tuning between layer resistivity and specific contact resistance, that is, in order to optimize the efficiency of the solar cell, experiments were initially carried out, in which layer resistivity and specific contact resistance are determined as a function of the pulse energy density of the laser radiation.

In this process, phosphoric acid with a concentration of 10 wt % phosphorus was applied as dopant source to the crystalline p-Si substrate by means of ultrasonic atomization. Afterwards, two thermal diffusions occurred in two separate diffusion furnaces.

Plotted in FIG. 1 are, on the one hand, the pulse energy density versus the layer resistivity ρ_{SH} and, on the other hand, the specific contact resistance versus the pulse energy density. It can be seen that, when the layer resistivity is reduced by at most 20%, there is a steep drop in the specific contact transition resistance at a pulse energy density of between 1.3 J/cm² and 1.5 J/cm².

Accordingly, for the production of solar cells and contacting of them, a laser radiation with a pulse energy density of between 1.3 J/cm² and 1.5 J/cm² is to be employed.

Furthermore, the dependence of internal quantum yield and pulse energy density ensues from FIG. 2. The curves highlight that, for a crystalline p-Si substrate and a dopant source applied thereto as described above at pulse energy densities of up to 1.5 J/cm², nearly no deterioration of the internal quantum yield occurs and only slight deterioration occurs at 1.78 J/cm².

Accordingly, it is ensured on the basis of the teaching of the invention that largely loss-free current conductance occurs, without undesired recombination of excess minority charge carriers occurring, which would lead to a deterioration of the efficiency of the solar cell.

If the teaching of the invention is described on the basis of the emitter region of a solar cell, the corresponding situation applies when electrically conductive contacts are produced in the base region according to the invention.

Further advantages and features of the teaching according to the invention ensue from the following example.

Multicrystalline wafers are isotextured and subsequently etched in an aqueous solution for 20 s at room temperature. The aqueous solution contains NaOH and H₂O₂ in a concentration of 5 wt % in each case and surfactant in a concentration of less than 0.01 wt %. After a cleaning in an aqueous solution containing 2 wt % HCl, the wafers are coated with an aqueous solution containing 10 wt % phosphorus in the form of phosphoric acid by use of absorbent foam rolls. Afterwards, phosphosilicate glass is produced at 920° C. for 20 min under an air atmosphere and phosphorus is diffused into the Si substrate. On account of the uniform coating with dopant and the high diffusion temperature, precipitates form homogeneously on the upper face of the solar cell. The layer resistivity lies above 150 Ohm/sq (Ω/). The Si wafers are then exposed to laser light locally at the sites on which the front-face metallization will later be printed. In this process, a disk laser with a wavelength of 532 nm is used. The repetition rate is 20 kHz, the pulse duration 30 ns. The laser spot has a round cross section with a diameter of approximately 50 μm. The overlap is 60%. The laser power is varied from cell to cell so that the pulse energy density lies in the range of 0.8 J/cm² to 3 J/cm². Additionally, several adjacently lying lines are lasered onto the wafers serving for optimization of the pulse energy density so that a rectangular area with dimensions of approximately 20×20 mm² is completely treated, with the overlap likewise being 60% in the 2nd direction. This measurement field is produced only on the set-up wafers and later serves for measurement of the layer resistivity in the lasered area. Alternatively, the layer resistivity can also be measured in the area of the likewise lasered current collection bars (busbars), which are, as a rule, wider than 1 mm and extend over the entire length of the solar cell. After removal of the phosphosilicate glass in HF with a concentration of 5 wt % for approximately 2 min, the wafers undergo diffusion at a temperature of 850° C. for 20 min in a second diffusion step. In this process, an advantageous diffusion profile is established in the inter-finger area and, at the same time, crystal damage present in the lasered area is partially repaired. After removal of the oxide layer, formed in the second diffusion step, by means of HF with a concentration of 5 wt % for approximately 1 min, the layer resistivities in the lasered area are measured in the measurement field intended for this and additionally laterally adjacent to the measurement field by means of 4-point measurement or alternatively by means of infrared thermography. After antireflection coating with SiN on the front face and front-face and back-side metallization, produced by means of screen printing of silver and aluminum pastes and a sintering step at temperatures above 800° C., the busbars of the set-up wafer are separated by means of laser or chip cutter, for example, and the contact transition resistances are determined by means of transfer length measurements. The measured values are then used to determine the pulse energy density range of the laser beam in which the layer resistivity in the lasered area is reduced between 0% and 30% compared to the layer resistivity outside of the lasered area and the specific contact resistance between the lasered area and the electrically conductive material applied thereto for forming the electrically conductive contact lies between 0 mΩcm² and 10 mΩcm². Finally, the remaining solar cells of a production period are likewise laser-treated, after isotexturing, hydrophilizing, application of phosphoric acid, HF etching, and a first diffusion step, albeit without the additional measurement field.

1-29. (canceled)

30. A method for producing contacts made of electrically conductive material on a solar cell, comprising:
homogeneously applying a dopant source to at least one side of a substrate made of crystalline silicon;
forming phosphosilicate glass by diffusing dopant into the substrate in a first thermal treatment;
locally applying laser radiation to the substrate in regions in which an electrically conductive material is to be applied in order to form the electrically conductive contact, wherein the phosphosilicate glass is removed before or after the application of the laser radiation;
measuring a layer resistivity developed in the surface region of the substrate on a dopant source side, both in and laterally outside of a lasered area, as a function of a pulse energy density of the laser radiation applied to the substrate;
applying the electrically conductive material to the lasered areas;
measuring a specific contact resistance between the lasered areas and the electrically conductive material applied thereto as a function of the pulse energy density of the laser beam applied to the substrate; and
determining a pulse energy density range of the laser beam from the measured values for which the layer resistivity in the lasered area is reduced an amount between 0% and 30% compared to the layer resistivity outside the lasered area and the specific contact resistance between the lasered area and the electrically conductive material applied thereto for forming the electrically conductive contact is between 0 mΩcm² and 10 mΩcm².

31. The method according to claim 30, further comprising applying laser radiation having a pulse energy density within the determined pulse energy density range to other solar cells to be contacted to the solar cell.

32. The method according to claim 30, wherein the amount the pulse energy density range is reduced is between 10% and 25%.

33. The method according to claim 30, wherein the dopant comprises a source selected from the group consisting of an aqueous solution, an alcoholic solution, a solid containing phosphorus as doping agent with a concentration between 2 atomic percent and 30 atomic percent.

34. The method according to claim 30, wherein, after formation of the phosphosilicate glass, the phosphosilicate glass is removed, after which the laser radiation is applied to the solar cell, and subsequently the substrate is exposed to a second thermal treatment step, and then the oxide formed on the substrate is removed.

35. The method according to claim 30, wherein, after formation of the phosphosilicate glass, laser radiation is applied to the solar cell and subsequently the phosphosilicate glass is removed, after which the substrate is exposed to a second thermal treatment step and then the oxide formed on the substrate is removed.

36. The method according to claim 30, wherein, after formation of the phosphosilicate glass, laser radiation is applied to the solar cell and subsequently the substrate is exposed to a second thermal treatment step, after which the phosphosilicate glass is removed.

37. The method according to claim 30, wherein, after formation of the phosphosilicate glass, the phosphosilicate glass is removed, then the substrate is exposed to a second thermal treatment step, after which the laser radiation is applied to the solar cell, and finally the oxide formed on the substrate is removed.

38. The method according to claim 30, wherein, after formation of the phosphosilicate glass, the phosphosilicate glass is removed, then the substrate is exposed to a second thermal treatment step, after which the oxide formed on the substrate is removed and, finally, laser radiation is applied to the solar cell.

39. The method according to claim 30, wherein, after formation of the phosphosilicate glass, the substrate is exposed to a second thermal treatment step, after which the laser radiation is applied to the solar cell and, finally, the phosphosilicate glass is removed.

40. The method according to claim 30, wherein, after formation of the phosphosilicate glass, the substrate is exposed to a second thermal treatment step, after which the phosphosilicate glass is removed and, finally, the laser radiation is applied to the solar cell.

41. The method according to claim 30, wherein the laser beam applied to the substrate is projected onto the substrate with a focus whose minimal width extension is at least 20 μm.

42. The method according to claim 30, wherein the laser radiation has a pulse energy density of between 1.0 J/cm² and 2.2 J/cm².

43. The method according to claim 30, wherein the first thermal treatment is carried out at a temperature between 800° C. and 990° C. for a time between 2 minutes and 90 minutes.

44. The method according to claim 30, wherein the laser radiation has a laser pulse duration of between 1 fs and 300 ns.

45. The method according to claim 30, wherein the laser radiation has a repetition rate of between 100 Hz and 1 MHz.

46. The method according to claim 30, wherein the laser radiation has a wavelength range of between 180 nm and 1200 nm.

47. The method according to claim 30, further comprising isotexturing the substrate prior to diffusion.

48. The method according to claim 30, wherein, prior to the application of the electrically conductive material, the ratio between content of active doping agent and total doping agent content in a thickness starting from the surface of the substrate between 90 nm and 110 nm is between 0.01 to 0.8.

49. The method according to claim 30, further comprising hydrophilizing the substrate prior to application of the dopant source.

50. The method according to claim 49, wherein the substrate is hydophilized in an aqueous solution containing a material selected from the group consisting of NaOH, KOH, H₂O, peroxide disulfate, and HCl.

51. A solar cell comprising:
a substrate made of crystalline silicon with an emitter;
electrically conductive contacts on certain areas of the substrate,
wherein the substrate has a surface extending on dopant side beneath the electrically conductive contacts with a layer resistivity of 0 to 25% less than the layer resistivity outside the electrically conductive contacts and the specific contact resistance between the electrically conductive contact and an edge region on the dopant source side lies between 0 mΩcm² and 10 mΩcm².

52. The solar cell according to claim 51, further comprising crystal defects present beneath the electrically conductive contacts over a thickness of between 1 nm and 200 nm starting from the edge region on the dopant source side.

53. The solar cell according to claim 51, wherein the layer resistivity of the substrate outside of the electrical contacts is 50 ohms per square to 250 ohms per square.

54. The solar cell according to claim 51, wherein the solar cell has a surface phosphorus concentration that is greater than 8×10²⁰ cm⁻³.
